(19) United States
(12) Patent Application Publication
(10) Pub. No.: US 2005/0225955 A1
(43) Pub. Date: Oct. 13, 2005

(54) Multi-layer printed circuit boards

(75) Inventors: John Grebenkemper, Saratoga, CA (US); Frank Mikalauskas, Victor, MT (US); Srinivasan Venkataraman, Santa Clara, CA (US); Jonathan Buck, Santa Clara, CA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(73) Assignee: Hewlett-Packard Development Company, L.P., Houston, TX (US)

(21) Appl. No.: 10/821,458

(22) Filed: Apr. 9, 2004

(51) Int. Cl. G01S 13/00; H05K 7/02; H05K 7/06; H05K 7/08; H05K 7/10

(52) U.S. Cl. 361/780

(57) ABSTRACT

A printed circuit board includes a power plane and a ground reference plane that includes two opposite sides. The power plane is positioned proximate one side of the ground reference plane. A signal layer is positioned proximate the other side of the ground reference plane to isolate the power plane from the signal layer. Any noise on the power plane or the signal layer is thus isolated by the intervening ground plane.

### BACKGROUND

A high performance computer system typically includes multiple levels of packaging to support signal connectivity, power distribution, heat dissipation and protection of various components. A printed wire board (or board) includes a number of devices encapsulated as modules or components and constitutes a level of packaging in the packaging hierarchy of an entire system. A computer system will include a number of boards, which support information processing units, system memory and I/O functions. Recent trends in server development include modular units or racks to enable system expansion through scaling and facilitate accessibility and serviceability. Each module may include a number of field replaceable and serviceable printed wire boards that connect through a back plane. These boards include various integrated circuits, which perform a number of functions as required by the system architecture.

Steep increases in on-chip device operating frequencies due to improvements in semiconductor processing techniques and manufacturing methods have continually pushed performance limits on systems or networks designed using these components. Performance on a bus interface, which has physical connectivity between components within a printed wire board or between components located on different boards does not scale with on-chip performance due to the limiting effects of component packaging and board level interconnect parasitics. Advanced electrical signaling protocols using sophisticated IO driver designs and packaging methods are continually developed to support data transfer at the board level between integrated circuit devices at very high bandwidth. These performance trends and the need to maintain compatibility with legacy devices or systems have increased the level of complexity at the board level to support components or devices with different process technologies, board level signaling protocols, component packaging and bandwidth requirements.

This necessitates the board design to support multiple core and I/O voltages. Power delivery requirements to support both core and I/O switching transients in a high performance component on a PCB is managed with various levels of charge caches, which could include on-die decoupling, component package decoupling, and decoupling capacitors located on the PCB. The on-die capacitance is quite effective since they have limited parasitics and are close in proximity to the devices that draw the current. The capacitances become less effective as the distance of their location from the current load increases due to the increase in inductive parasitics.

### SUMMARY

In some embodiments, a printed circuit board is provided that includes a first power plane and a first ground reference plane that includes two opposite sides. The first power plane is positioned proximate one side of the first ground reference plane. A first signal layer is positioned proximate the other side of the first ground reference plane to isolate the first power plane from the first signal layer. Any other signal layers in the printed circuit board are isolated from the first power plane by at least one ground reference plane.

In other embodiments, a method for stacking a multi-layer printed circuit board includes isolating all power planes in the printed circuit board from all signal layers in the printed circuit board by positioning a ground plane between each group of one or more of the power planes and each group of one or more of the signal layers.

In further embodiments, an electronic system includes a multi-layer printed circuit board that includes a plurality of power planes, a plurality of signal layers, and a ground plane positioned between each group of one or more of the plurality of power planes and each group of one or more of the signal layers. The ground plane(s) isolate the power planes from the signal layers.

### BRIEF DESCRIPTION OF THE FIGURES

Embodiments of systems, apparatus, and methods disclosed herein may best be understood by referring to the following description and accompanying drawings:

FIG. 1 shows a side view of an embodiment of a multi-layer printed circuit board in accordance with the present teachings;

FIG. 2 shows a component package mounted on a conventional multi-layer printed circuit board;

FIG. 3A shows a side view of a signal layer positioned between two voltage reference planes;

FIG. 3B shows a schematic diagram of a partial element equivalent circuit (PEEC) representation of loop inductance for the printed circuit board of FIG. 3A;

FIG. 4 shows another embodiment of the printed circuit board of FIG. 2 with a decoupling capacitor to correct an extra image current path;

FIG. 5 shows a side view of another embodiment of a printed circuit board in accordance with the present teachings;

FIG. 6 shows a side view of another embodiment of a printed circuit board in accordance with the present teachings;

FIG. 7 shows another embodiment of a printed circuit board in accordance with the present teachings;

FIG. 8 shows another embodiment of a printed circuit board in accordance with the present teachings; and

FIG. 9 shows an embodiment of a power plane configured with subplanes that can be utilized in a printed circuit board in accordance with the present teachings.

### DETAILED DESCRIPTION

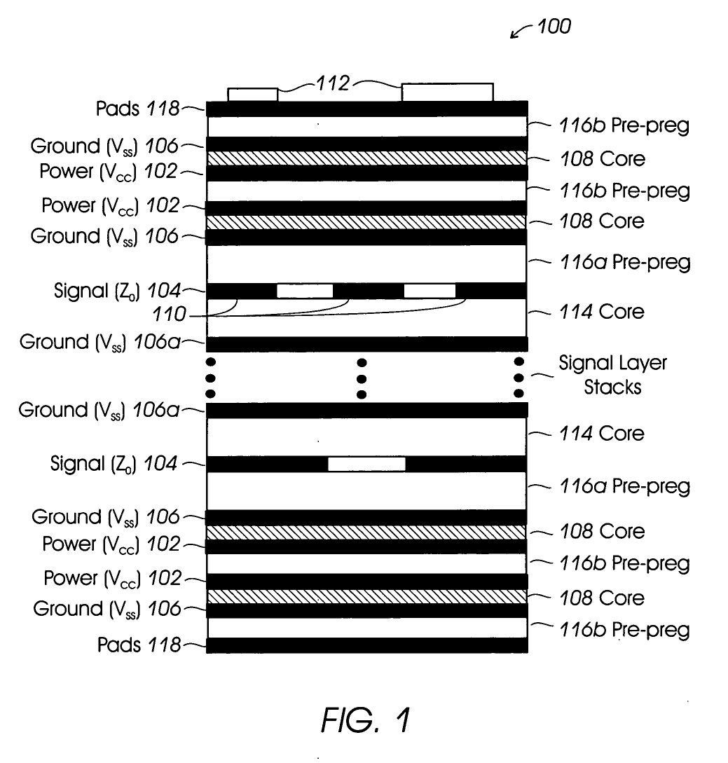

FIG. 1 shows an embodiment of PCB 100 with multiple layers including power planes 102 isolated from signal layers 104 by ground reference planes 106. Core layer 108 provides insulation between power planes 102 and ground reference planes 106. The dielectric material and the thickness of core layer 108 can be chosen to maximize the capacitance for one or more digital power voltages associated with power planes 102 and ground reference planes 106 without affecting the impedance or propagation velocity of signal layers 104. By isolating power planes 102 from signal layers 104, any noise on power planes 102 is isolated from signal traces 110 on signal layers 104 by intervening ground planes 106.

PCB 100 can improve power delivery to devices with multiple core and input/output (I/O) voltages compared to previous printed circuit board configurations. Embodiments of PCB 100 can minimize return current loops on high speed signal transmission paths between integrated circuits 112 on the PCB 100, as well as reduce the number of discrete components such as bypass capacitors required to support power delivery. Various configurations of PCB 100 can be utilized for a variety of purposes such as component packaging, multi-chip module packaging, and electronic printed circuit boards.

Signal layers 104 are designed to have controlled impedance (Z_{O}). Target impedance Z_{O} for a signal trace 110 on signal layer 104 is achieved by using specific cross sections for signal traces 110, and dielectric materials with specific thickness and dielectric constants (ε) for core layers 114 and pre-preg layers 116a. The dielectric materials typically have a low dielectric constant and low conductive loss properties at high frequencies to limit losses due to dispersion. Pre-preg layers 116a, 116b are typically sheets of material that include glass fibers impregnated with epoxy resin that can be positioned between layers of PCB 100 to bond the layers together. Pre-preg material is available with varying amounts of resin and glass fibers, which allows the thickness between layers to be chosen to provide an appropriate amount of resin flow between circuitry in PCB 100.

In the embodiment of PCB 100 shown in FIG. 1, power planes 102 and ground reference planes 106 provide voltage to various integrated circuits 112 mounted on PCB 100. Connectivity between integrated circuits 112 is established through the controlled impedance signal traces 110, which reference to power planes 102 and ground planes 106. Large current slew rate demands from integrated circuit 112 can result in substantial amounts of switching current during normal operation. The switching current creates noise transients on power planes 102 and ground reference planes 106. In conventional printed circuit boards, this noise could affect signals being transmitted to other integrated circuits 112 and, if large enough, could cause the integrated circuits 112 to receive, compute, and/or transmit incorrect data. PCB 100 isolates power planes 102 from signal layers 104, however, thereby allowing freedom to adjust dielectric material properties and thickness of core layers 108 and pre-preg layers 116b to improve power delivery without adversely impacting signal propagation on signal traces 110. Thin dielectric core layers 108, and pre-preg layers 116b helps to lower the power distribution impedance through layers of PCB 100. Dielectric material with larger dielectric constant properties can be used to increase the charge storage capacity of power distribution through layers of PCB 100.

In traditional PCB designs, signal traces 110 could be referenced to one or more power planes 102. Power planes 102 and ground reference planes 106 conduct image currents from signal traces 110, which require bypass capacitors to provide a path for image currents flowing on power planes 102 to return to the ground plane 106 to complete a current loop. If current return paths to ground are not minimized by design, the return paths manifest themselves as additional discontinuities in the signal propagation path causing signal distortion. The impact of return path discontinuities on signal propagation is more pronounced with faster signaling edge rates.

One way to minimize return current paths is to place numerous bypass capacitors (not shown) on top or bottom pads layer 118 and connect the capacitors between power planes 102 and ground planes 106 using vias (not shown). However connections through vias from bypass capacitors to power planes 102 and ground planes 106 add additional series inductance and resistance, which limits the effectiveness of bypassing return currents at high frequencies. Isolating power planes 102 from signal layers 104 as disclosed herein results in signal layers 104 referencing only ground planes 106a, which effectively minimizes image current paths. The number of decoupling capacitors used specifically to shunt return currents during input/output switching activity is therefore reduced by isolating power planes 102 from signal layers 104.

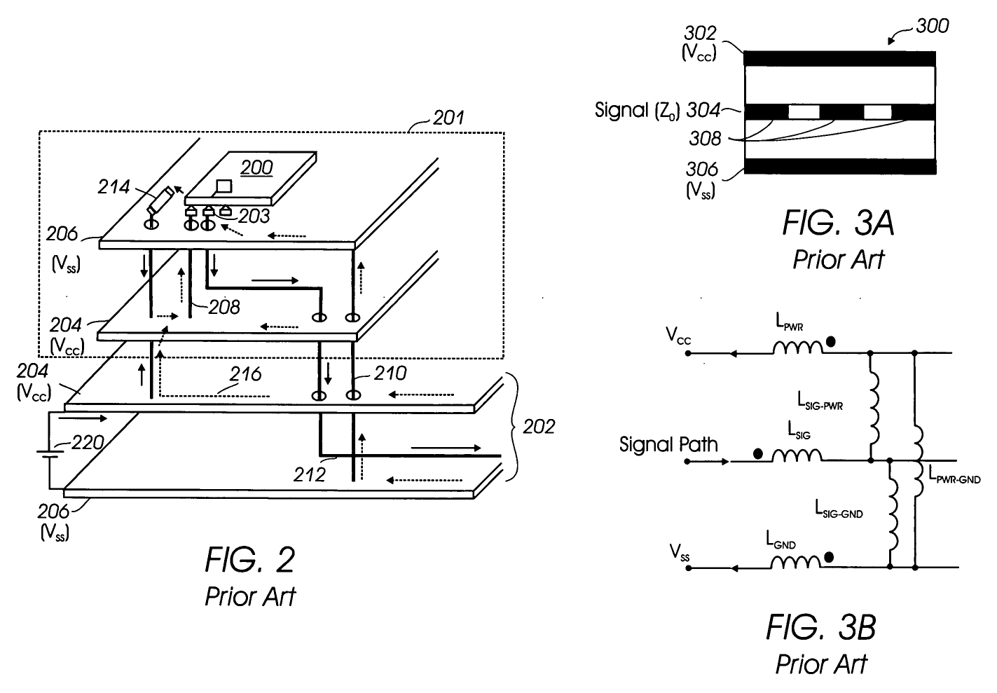

FIG. 2 shows silicon die 200 representing electronic circuitry in multi-layer component package 201. Component package 201 is mounted on a conventional printed circuit board 202. Ball grid array connections (not shown) on component package 201 attach to surface pads (not shown) on the printed circuit board 202. Multiple stacks of signal layers (not shown), power reference planes 204, and ground reference planes 206 may be included with component package 201 and printed circuit board 202 to support the signal routing and current density requirements. Power vias 208 and ground vias 210 connect to respective power planes 204 and ground planes 206 in component package 201 and printed circuit board 202. Signal trace 212 is configured to provide a controlled impedance path from silicon die 200 to a receiving device (not shown) located on a different component package (not shown) mounted on printed circuit board 202. Note that signal trace 212 also connects vertically through vias across the multi-layer component package 201 and the multi-layer printed circuit board 202.

The current paths for a positive assertion (logic high) on signal trace 212 to and from silicon die 200 are shown by solid arrows. The image return paths are shown by arrows with dashed lines. The asserting silicon die 200 can draw current from different levels of charge caches, which includes decoupling built in to the silicon integrated circuit (not shown), component package level decoupling such as decoupling capacitor 214 included in component package 201, and printed circuit board level decoupling (not shown) to support the transient without significant voltage drop. Charge caches, such as decoupling capacitors 214 provide charge to support the switching transient of silicon die 200. Charge transfer using on-chip, also referred to as on silicon, decoupling capacitors (not shown) can be very efficient since a local current loop within the silicon die 200 is used that is not affected by parasitics of component package 201. Charge transfer capacity of decoupling capacitor 214 is, however, limited. Accordingly, charge transfer from decoupling capacitors 214 to silicon die 200 are typically designed with low inductance paths to enable efficient charge transfer to support the current load transient (di/dt) and to allow for efficient charge replenishment of capacitors 214. PCB 100 (FIG. 1) and other embodiments disclosed herein can support very efficient charge transfer capability from PCB 100 to all devices or components, such as silicon die 200.

FIG. 2 shows an extra current path 216 taken by the image current on power plane 204 as silicon die 200 transmits signals on signal trace 212 to a logical high digital voltage level. Current path 216 occurs due to lack of a shorter path for the high frequency image current on power plane 204 to return back to component package 201. The image current will use the nearest power pin on component package 201. The impact of current path 216 can be explained with the concept of partial inductances in which an interconnect path constitutes per unit length inductance and capacitance distributed from a driving device to a receiving device. The inductance per unit length (or loop inductance) of the interconnect path can be mathematically represented as partial inductances as follows:
Lₗₒₒₚ=L_{sig}+L_{ref}−[2*L_{sig-ref}] (Equation (1))
where Lₗₒₒₚ is the loop inductance of the current path;
L_{sig} is the partial self-inductance of signal trace 212;
L_{ref} is the partial self-inductance of the reference plane; and
L_{sig-ref} is the partial mutual inductance between signal trace 212 and the reference plane.

FIG. 3A shows a side view of a printed circuit board 300 with power plane 302, signal layer 304, and ground plane 306. FIG. 3B shown an equivalent circuit representation of the concept of partial inductances for PCB 300 in FIG. 3A. With the presence of a power plane 302 and ground plane 306 as reference planes, Equation (1) can be rewritten as
Lₗₒₒₚ=L_{sig}−L_{sig-pwr}−L_{sig-gnd}+[[L_{pwr}+L_{pwr-gnd}−L_{sig-pwr}]∥[L_{gnd}+L_{pwr-gnd}−L_{sig-gnd}]] (Equation (2))
where the operator ∥ represents forming the equivalent inductance for two inductors connected in parallel. Assuming symmetry on the signal trace with respect to the voltage reference planes,
L_{pwr}=L_{gnd} and L_{sig-pwr}=L_{sig-gnd} (Equation (3)).
Equation (2) reduces to
Lₗₒₒₚ=L_{sig}−2[L_{sig-gnd}]+[0.5[L_{gnd}+L_{pwr-gnd}−L_{sig-gnd}]] (Equation (4)).

The loop inductance in Equation (4) is valid as long as there is a very low impedance path for all frequency components from node V_{CC} on power plane 302 to node V_{SS} on ground plane 306 and the characteristic impedance remains Zₒ=SQRT [Lₗₒₒₚ/C], where C is the capacitance per unit length of signal trace 308. The extra current path 216 in FIG. 2 increases the partial self inductance of ground plane 206, which in effect alters the characteristic impedance of signal trace 212. Thus, current path 216 increases signal propagation delay, and also increases cross-talk due to return current overlap on power planes 204 from many signal traces 212.

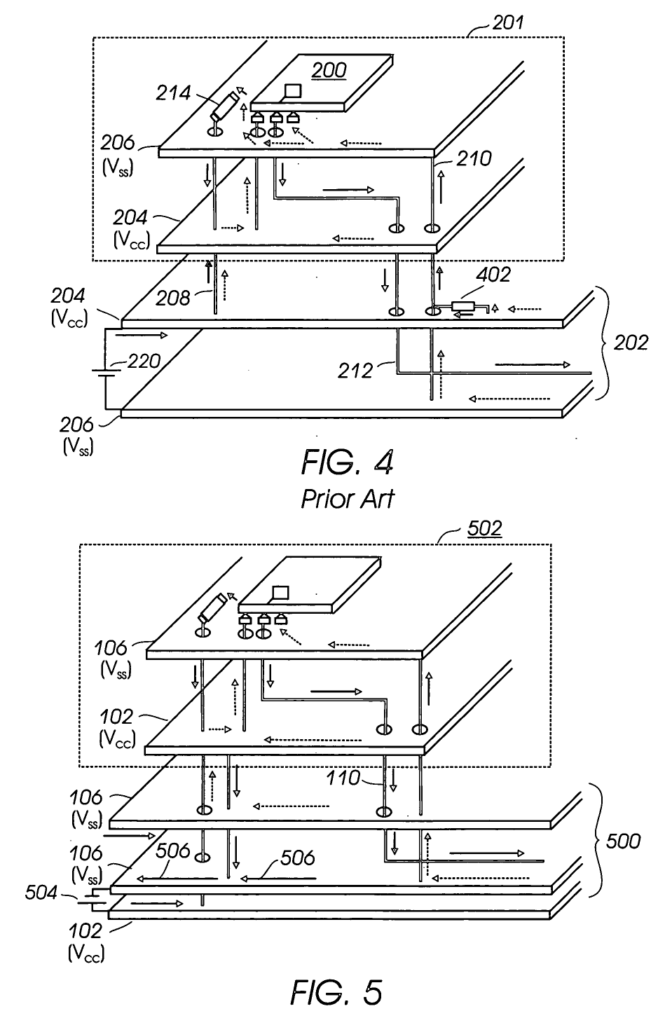

The impact of extra current path 216 can be corrected if there is a power pin connection close to the signal pin connection on component package 201. The impact of extra current path 216 can also be corrected as shown in FIG. 4 by adding decoupling components such as decoupling capacitors 402 at the interface between component package 201 and PCB 202.

Referring now to FIG. 5, all data signal traces 110 are referenced only to ground planes 106 on printed circuit board 500, which ensures the shortest image current return paths without using decoupling capacitors 402 (FIG. 4) at the interface between component package 502 and PCB 500. Bulk power is supplied by voltage source 504 attached across the Vcc ground planes 106 and Vss power planes 102 to support charge replenishment and current requirements over many periods of switching activity. In some instances, such as high performance microprocessors, bulk voltage source 504 couples directly to power planes 102 and ground planes 106 of component package 502 for efficient very low inductance power distribution. Low and very low frequency image current components 506 spread along the ground reference planes 106 as current components 506 return to voltage source 504 using the shortest DC resistance path. In contrast, high frequency image current components are constricted by field lines to flow right under signal traces 110 as image currents over the path of lowest impedance.

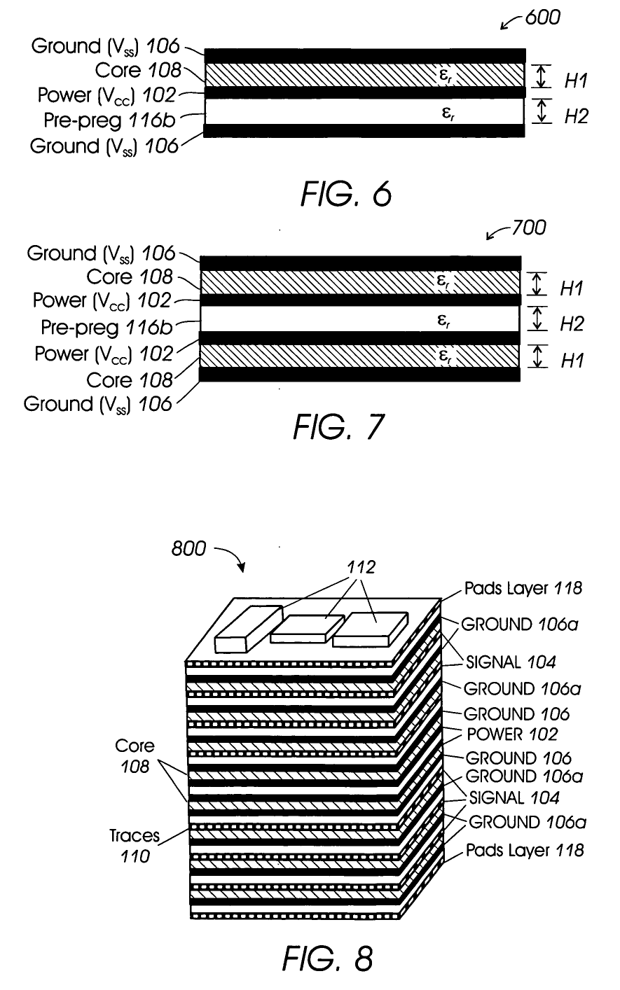

In some embodiments, separate core layer 108, and pre-preg layer 116b for power planes 102 and ground planes 106 can be configured in PCB 100 as shown in FIGS. 6 and 7. FIG. 6 shows a very low thickness (H1) dielectric core layer 108 and an additional pre-preg layer 116b with thickness (H2) in PCB 600 with ground planes 106 isolating power plane 102. Ground planes 106 isolate power plane 102 as well as core layer 108 and pre-preg layer 116b from signal layers (not shown), which can be present above and below ground planes 106 in multilayer PCB 600. The dielectric material and thickness used for core layer 108 and pre-preg layer 116b has no impact on the propagation velocity or the impedance of any of the signal layers. Accordingly, materials with very high dielectric constants E and with the lowest thickness, for example, less than approximately 1 mil, can be used for the core layer 108 and pre-preg layer 116b to maximize buried capacitance (C) between power plane 102 and ground plane 106 according to the following equation:
C/[area]=εᵣεₒ/thickness (Equation (5))
where εₒ is the permittivity of free space, and εᵣ is the relative permittivity of the dielectric material, which can be used as core layer 108 and/or pre-preg layer 116b.

Positioning power planes 102 adjacent to ground planes 106 as described above will result in lower impedance for power distribution. The lower impedance is due to the very low loop inductance (Lₗₒₒₚ) path that can be achieved from PCB 600 to components, such as component packages 502 (FIG. 5), located on PCB 600. Using the partial element equivalent circuit concept, the loop inductance across an adjacent power plane 102 and ground plane 106 is given by:
Lₗₒₒₚ=L_{pwr}+L_{gnd}−[2*L_{pwr-gnd}] (Equation (6)).
Where Lₗₒₒₚ is the loop inductance of the power-ground plane pair;
L_{pwr} is the partial self inductance of power plane 102;
L_{gnd} is the partial self inductance of the ground plane 106; and
L_{pwr-gnd} is the partial mutual inductance between power plane 102 and ground plane 106.

Note that the loop inductance can be minimized by reducing the thickness between the power planes 102 and ground planes 106. PCBs 600 with power planes 102 isolated by ground planes 106 can be located on top of another multi-layer PCB (not shown), which would require the shortest via connections from power planes 102 and ground planes 106 to the power and ground pins of component package(s) mounted on PCB 600.

The configuration of PCB 600 can be extended to support multiple power planes 102 as shown in FIG. 7. PCB 700 includes two core layers 108 (with thickness H1) and a pre-preg layer 116b (with thickness H2). Ground planes 106 isolate power planes 102 from the signal layers (not shown).

Referring to FIGS. 1, 6, and 7, PCBs 600 and 700 can be inserted anywhere in the overall design of the printed circuit board multi-layer stack-up. FIG. 1 shows PCB 100 with ground planes 106 and power planes 102 near the top and bottom layers to maintain overall board symmetry. In some embodiments, power planes 102 located near the bottom pads layer 118 of PCB 100 can be optimized for enhanced power delivery by assigning power planes 102 near the bottom pads layer 118 to supply digital voltages to components located on the bottom side of PCB 100. The controlled impedance signal layers 104 are referenced to only ground planes 106 and are stacked in the center portion of PCB 100 as shown.

PCB 100 includes one side of core layers 114 configured with signal traces 110 and another side configured with ground planes 106. In other embodiments, PCB 100 can include signal layers 104 on both sides of pre-preg layers 116a and/or core layers 114. In the embodiment of PCB 100 shown, each signal layer 104 is separated from other signal layers 104 by a ground reference plane 106. Single layers of signal traces 110 can simplify routing signal traces 110 between components, such as integrated circuits 112, of PCB 100. For example, running two or more signal traces 110 parallel and very close to each other on two adjacent signal layers 104 over long distances on PCB 100 can create excessive crosstalk. Routing signal traces 110 orthogonal to each other on adjacent signal layers 104 can help reduce crosstalk, however, the ability to route signal traces 110 regardless of their orientation to signal traces 110 on adjacent signal layers 104 can provide greater flexibility in designing PCB 100.

Referring now to FIG. 8, another embodiment of a PCB 800 with power planes 102 isolated from signal layers 104 is shown including power planes 102 positioned near the central portion of PCB 800. Ground reference planes 106 shield signal layers 104 from power planes 102. PCB 800 is shown with signal traces 110 on one side of core layers 108, however, PCB 800 can include signal layers 104 on one or both sides of pre-preg layers 116a and/or core layers 108.

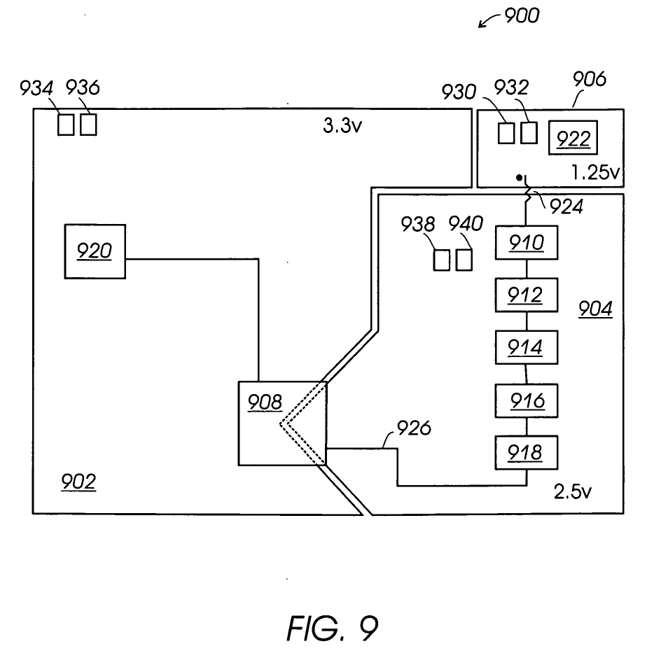

Referring to FIGS. 1 and 9, in some embodiments, different integrated circuits 112, as well as other components that may be mounted on or within PCB 100, may require different levels of operating voltage. FIG. 9 shows a top view of power plane 900 configured with three subplanes 902, 904, 906 that provide different levels of voltage, such as 3.3 volts, 2.5 volts, and 1.25 volts, respectively. Signal traces 110 on signal layers 104 are not affected by cuts in power plane 102 as they are physically shielded from power planes 102 by ground planes 106.

In the example shown, integrated circuit 908 has a unique core voltage power requirement of 1.8 volts. The two input/output (I/O) voltages on integrated circuit 908 are 3.3 volts and 2.5 volts. Integrated circuits 910, 912, 914, 916, 918 use 2.5 volts power for both core and I/O power connections. Integrated circuit 920 uses 3.3 volts for both core and I/O power, while integrated circuit 922 supplies a termination voltage of 1.25 volts to a memory bus interface 926. The termination voltage is used by termination resistors 924 wired to a memory bus 926.

Power plane 900 is an example of a configuration that requires multiple core and I/O voltages by various components with different process technologies and I/O signaling protocols. A low inductance power delivery path to support all the above mentioned voltages can be easily designed into PCB 700 using two power layers 102 between ground layers 106 as shown in FIG. 7. Specifically, power plane 900 can be split under the image of the components to support 3.3 volts, 2.5 volts and 1.25 volts as shown in FIG. 9. Note that power plane 900 is split for 3.3 volts and 2.5 volts under the image of the pin field for integrated circuit 908. Another power plane 102 in PCB 700 can be used to support 1.8 volts requirement for integrated circuit 908. All the voltages benefit from the high 6r dielectric with low loop inductance paths to the component power and ground pins, making the decoupling scheme very efficient. Note that the splits in power plane 102 do not impact the impedance of signal layers 104 as signal layers 104 are only referenced to ground planes 106. Signal traces 110 do not cross cuts in power plane 900, which eliminates constraints while routing signals across splits or between subplanes 902, 904, 906.

In some embodiments of power plane 900, additional discrete capacitors 930 through 940 can be located on top and/or bottom of power plane 900 to directly connect to the respective subplanes 902, 904, 906 using multiple vias to achieve the lowest loop inductance paths to the components such as integrated circuits 908 through 922. Devices such as decoupling capacitors 930 and 932 can be used to support the termination voltage of 1.25 volts during transient switching of bus interface 926. Decoupling capacitors 930, 932 can be located directly above or below subplane 906 to allow direct connectivity to power plane 900 with vias (not shown). In the embodiment shown, decoupling capacitors 934 and 936 are designated for 3.3 volts, while capacitors 938 and 940 are designated for 2.5 volts.

Embodiments of PCBs in accordance with the present teachings can be configured with any suitable number of power planes 102, ground planes 106, and signal layers 104. Further, a combination of power planes 102 positioned near one or both outer surfaces, and/or in the central portion of a PCB can be utilized, based on the requirements of a particular configuration. Any suitable number of subplanes 902, 904, 906 can be provided on one or more power planes 102 to supply the required levels of voltage. Additionally, embodiments of PCBs 100, 600, 700 can be utilized in any type of suitable device such as computers, stereo systems, telephones, personal digital assistants, televisions, microwaves, automobiles, aircraft, and spacecraft, among others.

PCB 100 can range in size from less than one square inch to several square feet. Embodiments of PCB 100 disclosed herein can be used for any suitable components, such as integrated circuits 112 to reduce unwanted noise. Further, any suitable materials and fabrication techniques for PCB 100 can be utilized.

Integrated circuits 112 can embody various types of devices that operate at different frequencies, voltages, and currents. Some types of integrated circuits can be more susceptible to noise, while others are immune from noise considerations. Accordingly, different types of integrated circuits 112 can be grouped together, with space between different groups to reduce exposing neighboring circuits to noise. Additionally, signal traces 110 for a group of similar integrated circuits 112 can be routed to avoid other types of circuits. Further, isolating power planes 102 from signal layers 104 can help reduce any difficulties associated with grouping types of integrated circuits 112 and associated traces 110 to achieve acceptable performance in a particular design.

While the present disclosure describes various embodiments, these embodiments are to be understood as illustrative and do not limit the claim scope. Many variations, modifications, additions and improvements of the described embodiments are possible. For example, those having ordinary skill in the art will readily implement the processes necessary to provide the structures and methods disclosed herein. Variations and modifications of the embodiments disclosed herein may also be made while remaining within the scope of the following claims. In the claims, unless otherwise indicated the article “a” is to refer to “one or more than one”.

1. A printed circuit board comprising:
a first power plane;
a first ground reference plane including two opposite sides, wherein the first power plane is positioned proximate one side of the first ground reference plane; and
at least one signal layer, wherein the at least one signal layer is positioned proximate the other side of the first ground reference plane to isolate the first power plane from the at least one signal layer;
wherein any other signal layers in the printed circuit board are isolated from the first power plane by at least one ground reference plane.

2. The printed circuit board of claim 1, wherein the first power plane and the first ground reference plane are positioned near the surface of the printed circuit board.

3. The printed circuit board of claim 1, further comprising a second ground reference plane, wherein the first power plane is positioned among inner layers of the printed circuit board between the first and second ground reference planes.

4. The printed circuit board of claim 1, further comprising a second ground reference plane and a second power plane, wherein:
the printed circuit board includes outer surfaces,
the first power plane and the first ground reference plane are positioned proximate a first outer surface of the printed circuit board,
the second power plane and the second ground reference plane are positioned proximate a second outer surface of the printed circuit board, and
the first signal layer is positioned between the first and second ground reference planes to isolate the first signal layer from the first and second power planes.

5. The printed circuit board of claim 1, further comprising:
a first insulating layer positioned between the first ground reference plane and the first power plane;
a second insulating layer positioned between the first ground reference plane and the at least one signal layer.

6. The printed circuit board of claim 1, further comprising an insulating layer positioned between the first ground reference plane and the first power plane, wherein the insulating layer is configured provides capacitance between the first ground reference plane and the first power plane.

7. The printed circuit board of claim 1, wherein the first power plane includes at least two different subplanes configured to provide different voltages.

8. A method for stacking a multi-layer printed circuit board comprising:
isolating all power planes in the printed circuit board from all signal layers in the printed circuit board by positioning a ground plane between each group of one or more of the power planes and each group of one or more of the signal layers.

9. The method of claim 8, further comprising:
configuring the ground plane to provide a voltage reference for at least one of the signal layers.

10. The method of claim 8, wherein the power planes, the ground planes, and the signal layers include conductive material, the method further comprising:
forming insulating layers between the layers that include conductive material.

11. The method of claim 8, further comprising:
configuring the first power plane with a plurality of subplanes, wherein each subplane provides a different voltage.

12. The method of claim 8, further comprising:
positioning the power planes proximate the middle layers of the printed circuit board.

13. The method of claim 8, further comprising:
positioning the power planes proximate at least one outer layer of the printed circuit board.

14. The method of claim 8, further comprising:
positioning a pads layer on the surface of the printed circuit board.

15. The method of claim 8, further comprising:
positioning an integrated circuit on the pads layer.

16. An electronic system comprising:
a multi-layer printed circuit board including:
a plurality of power planes;
a plurality of signal layers; and
a plurality of ground planes, wherein at least one of the plurality of ground planes is positioned between each group of one or more of the plurality of power planes and each group of one or more of the signal layers to isolate each of the groups of one or more of the power planes from each of the groups of one or more of the signal layers.

17. The electronic system of claim 16, wherein at least a portion of the plurality of signal layers include signal traces on a single side of a core layer.

18. The electronic system of claim 16, wherein at least a portion of the plurality of signal layers include signal traces on two sides of a core layer.

19. The electronic system of claim 16, further comprising:
an insulating layer positioned between each of the power planes, the ground plane, and the signal layers.

20. The electronic system of claim 16, further comprising:
a ground plane positioned proximate each of the signal layers.

21. The electronic system of claim 16, further comprising:
a pads layer positioned on at least one outer surface of the printed circuit board.

22. The electronic system of claim 16, further comprising:
an integrated circuit mounted on the printed circuit board.

23. The electronic system of claim 16, wherein a plurality of power planes are positioned adjacent to a ground plane and separated by an insulating layer of thickness of approximately less than 1 mil.
